(19) United States
(12) Patent Application Publication
(10) Pub. No.: US 2026/0123225 A1
(43) Pub. Date: Apr. 30, 2026

(54) DISPLAY APPARATUS

(71) Applicant: LG Display Co., Ltd., Seoul (KR)

(72) Inventors: KwangHyun Baek, Paju-si (KR); Hyunjik Bae, Paju-si (KR); Yoonji Choi, Paju-si (KR)

(73) Assignee: LG Display Co., Ltd., Seoul (KR)

(21) Appl. No.: 18/984,240

(22) Filed: Dec. 17, 2024

(30) Foreign Application Priority Data
Dec. 29, 2023 (KR) 10-2023-0196753

(51) Int. Cl. H10K 59/35; H10K 59/122

(52) U.S. Cl. CPC H10K 59/353; H10K 59/122

(57) ABSTRACT

A display apparatus is capable of improving aperture ratio and luminance of a light emitting area. The display apparatus in one example includes a display area having a plurality of first light emitting areas having a first color and arranged in a first direction. An interval between the first light emitting areas adjacent in the first direction can alternate between a maximum interval and a minimum interval being smaller than the maximum interval along the first direction.

### CROSS-REFERENCE TO RELATED APPLICATION

This application claims priority to Korean Patent Application No. 10-2023-0196753, filed in the Republic of Korea on Dec. 29, 2023, the entire contents of which is hereby expressly incorporated by reference into the present application.

### BACKGROUND

### Technical Field

The present disclosure relates to a display apparatus.

### Discussion of the Related Art

An electroluminescent display apparatus has advantages of using light emitting elements, high luminance, low driving voltage, ultra-thin film, and free shape.

The electroluminescent display device can include a light cutting film (LCF) built into a display panel to limit a vertical viewing angle by cutting the vertical viewing angle depending on the use.

In the electroluminescent display apparatus with a built-in LCF, the light emitting area of the light emitting element in each subpixel can have a long stripe shape in the left and right directions, and light emitting areas of the same color can be arranged in the left and right directions.

Since there is a minimum gap margin, which is a dead zone, between the openings of a fine metal mask (FMM) used to form a light emitting element, the longest light emitting area in the left and right directions among the plurality of light emitting areas has limitations in increasing aperture ratio and luminance.

### SUMMARY OF THE DISCLOSURE

Accordingly, the present disclosure is directed to providing a display apparatus that substantially obviate one or more problems due to limitations and disadvantages of the related art.

An aspect of the present disclosure provides a display apparatus capable of improving aperture ratio and luminance of a light emitting area.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these and other advantages and in accordance with the purpose of the disclosure, as embodied and broadly described herein, there is provided a display apparatus comprising a display area including a plurality of first light emitting areas having a first color and arranged in a first direction, wherein an interval between first light emitting areas adjacent in the first direction can alternate between a maximum interval and a minimum interval smaller than the maximum interval along the first direction.

In accordance with another aspect of the present disclosure, there is provided a display apparatus comprising a display area including first to sixth row lines extending in a first direction and arranged in a second direction crossing the first direction, wherein each of the first and fourth row lines includes a plurality of first subpixels in which a plurality of first light emitting areas are arranged along the first direction, each of the second and fifth row lines includes a plurality of second subpixels in which a plurality of second light emitting areas are arranged along the first direction, the third row line includes a plurality of 3 -1subpixels and 3-2 subpixels in which a 3-1 light emitting area and a 3-2 light emitting area are alternately arranged along the first direction, and the sixth row line includes a plurality of 3-2 subpixels and 3-1 subpixels in which the 3-2 light emitting area and the 3-1 light emitting area are alternately arranged along the first direction. In each of the third and sixth row lines, the 3-1 light emitting area and the 3-2 light emitting area adjacent to each other in the first direction can be spaced apart by a maximum interval, and the 3-2 light emitting area and the 3-1 light emitting area adjacent to each other in the first direction are spaced apart by a minimum interval smaller than the maximum interval.

In accordance with another aspect of the present disclosure, there is provided a display apparatus comprising a pixel array including a plurality of pixels arranged in a first direction and a second direction crossing the first direction, each of the pixels including a plurality of light emitting elements, one light emitting element among the plurality of light emitting elements having a largest light emitting area greater than that of the remaining light emitting element, an encapsulation layer disposed on the pixel array to seal a light emitting element layer including the light emitting element, a touch sensor array comprising a black matrix and a sensor electrode disposed on the encapsulation layer and overlapping a non-emission area of the pixel array, and a light control array including a light control element disposed on the touch sensor array and overlapping the light emitting element. In in the pixel array, in an N−1th (N is an integer of 2 or more) pixel and an Nth pixel adjacent to each other in the first direction, light emitting elements having the largest light emitting area are adjacent to each other and spaced apart at a first distance in the first direction, and in the Nth pixel and an N+1th pixel adjacent to each other in the first direction, light emitting elements having the largest light emitting area are adjacent to each other and spaced apart at a second distance smaller than the first distance in the first direction.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram schematically illustrating an example of a configuration of a display apparatus according to an embodiment of the present disclosure.

FIG. 2 is a cross-sectional view schematically illustrating an example of a structure of a display panel according to an embodiment of the present disclosure.

FIG. 3 is a diagram schematically illustrating a configuration of a subpixel according to an embodiment of the present disclosure.

FIG. 4 is an equivalent circuit diagram illustrating an example of a configuration of a subpixel according to an embodiment of the present disclosure.

FIG. 5 is a diagram illustrating an example of a driving waveform of a subpixel according to an embodiment of the present disclosure.

FIG. 6 is an enlarged plan view illustrating an example of a plurality of pixel areas of a display apparatus according to an embodiment of the present disclosure.

FIG. 7 is a cross-sectional view schematically illustrating an example of a structure of a plurality of second subpixel regions taken along line I-I′ in FIG. 6.

FIG. 8 is a cross-sectional view schematically illustrating an example of structure of a plurality of third subpixel regions taken along line II-II′ in FIG. 6.

FIG. 9 is an enlarged plan view illustrating an example of a pixel area according to an embodiment of the present disclosure.

FIG. 10 is a plan view illustrating an example of a first mask according to an embodiment of the present disclosure.

FIG. 11 is a plan view illustrating an example of a second mask according to an embodiment of the present disclosure.

FIG. 12 is a plan view illustrating an example of a third mask according to an embodiment of the present disclosure.

FIG. 13 is a schematic diagram schematically illustrating an example of a method of depositing a second light emitting layer of a display apparatus according to an embodiment of the present disclosure.

FIG. 14 is a schematic diagram schematically illustrating an example of a method of depositing a third light emitting layer of a display apparatus according to an embodiment of the present disclosure.

FIG. 15 is a cross-sectional view illustrating an example of an overall structure of a second subpixel area taken along a line III-III′ in FIG. 6.

FIG. 16 is a cross-sectional view illustrating an example of an overall structure of a third subpixel area along a line IV-IV′ in FIG. 6.

FIG. 17 is a cross-sectional view illustrating an example of another structure of a third subpixel region according to an embodiment of the present disclosure.

### DETAILED DESCRIPTION OF THE EMBODIMENTS

Advantages and features of the present disclosure, and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing aspects of the present disclosure are merely an example, and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted. In a case where ‘comprise’, ‘have’, and ‘include’ described in the present disclosure are used, another part can be added unless ‘only’ is used. The terms of a singular form can include plural forms unless referred to the contrary.

In construing an element, the element is construed as including an error range although there is no explicit description.

In describing a position relationship, for example, when a position relation between two parts is described as “on,” “over,” “under,” and “next,” one or more other parts can be disposed between the two parts unless a more limiting term, such as “just” or “direct (ly)” is used.

In describing a time relationship, for example, when the temporal order is described as, “after,” “subsequent,” “next,” and “before,” a case which is not continuous can be included unless a more limiting term, such as “just,”“immediate (ly),”or “direct (ly)” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

In describing the elements of the present disclosure, the terms “first,” “second,” “A,” “B,” “(a),” “(b),” etc., can be used. These terms are intended to identify the corresponding elements from the other elements, and basis, order, sequence, or number of the corresponding elements should not be defined or limited by these terms. As for the expression that an element or a layer is “connected,” “coupled,” or “adhered” to another element or layer, the element or layer may not only be directly connected or adhered to another element or layer, but also be indirectly connected or adhered to another element or layer with one or more intervening elements or layers “disposed”between the elements or layers, unless otherwise specified.

The term “at least one” should be understood as including any and all combinations of one or more among the associated listed elements. For example, the meaning of “at least one or more of a first element, a second element, and a third element” denotes the combination of all elements proposed from two or more of the first element, the second element, and the third element as well as the first element, the second element, or the third element. Further, the term “can” fully encompasses all the meanings and coverages of the term “may.”

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Hereinafter, the aspects of the present disclosure will be described with reference to the accompanying drawings. Since a scale of each of elements shown in the accompanying drawings is different from an actual scale for convenience of description, the present disclosure is not limited to the shown scale. Further, all the components of each display apparatus according to all aspects of the present disclosure are operatively coupled and configured.

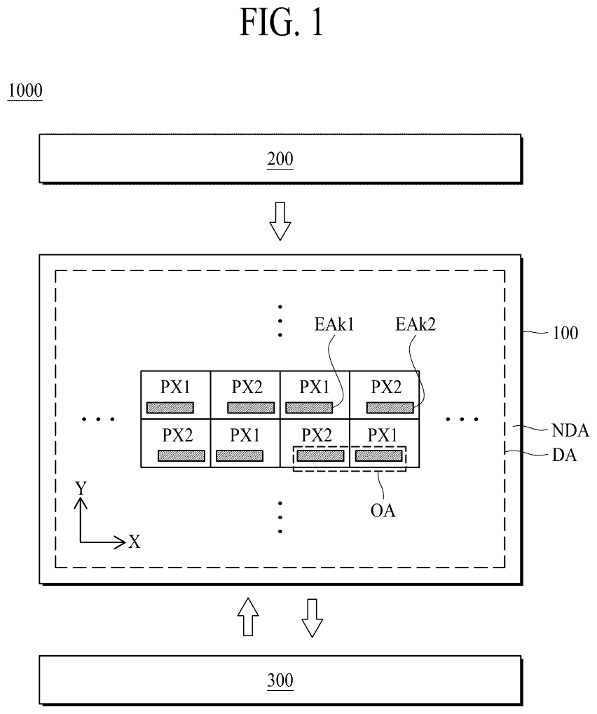

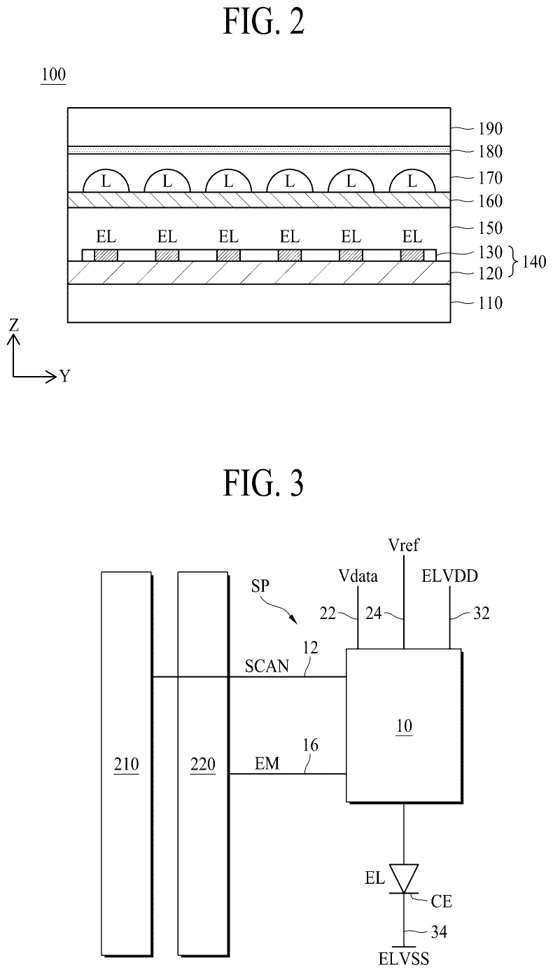

FIG. 1 is a diagram schematically illustrating an example of a configuration of a display apparatus according to an embodiment of the present disclosure, FIG. 2 is a cross-sectional view schematically illustrating an example of a structure of a display panel according to an embodiment of the present disclosure, and FIG. 3 is a diagram schematically illustrating a configuration of a subpixel according to an embodiment of the present disclosure.

Referring to FIGS. 1 to 3, the display apparatus 1000 according to an embodiment can provide both a display function for displaying an image and a touch sensing function for sensing the presence or absence of a user's touch and/or touch coordinates.

The display apparatus 1000 according to an embodiment can be an electroluminescent display apparatus including a touch sensor or a micro light emitting diode display apparatus. An electroluminescent display apparatus including a touch sensor can be an organic light emitting diode (OLED) display apparatus, a quantum-dot light emitting diode display apparatus, or an inorganic light emitting diode display apparatus.

Referring to FIG. 1, the display apparatus 1000 can include a display panel 100, a display driving circuit 200 for driving the display panel 100, and a touch sensing circuit 300 for driving and sensing a touch sensor array embedded into the display panel 100. The display apparatus 1000 can further include a power management circuit for generating and supplying a plurality of power voltages required for operations of the display panel 100, the display driving circuit 200, and the touch sensing circuit 300.

The display panel 100 can be a rigid display panel, or a flexible display panel capable of shape deformation such as a foldable, bendable, rollable, and stretchable display panel.

The display panel 100 can include a display area DA for displaying an image and a non-display area NDA that is a bezel area surrounding the display area DA and positioned at the outer portion. The non-display area NDA can surround the display area DA entirely or only in part(s).

The display panel 100 can further include a touch sensor array disposed in the display area DA to sense a user's touch.

The display panel 100 can display an image using the display area DA in which a plurality of subpixels is arranged in a matrix form. The pixel matrix of the display area DA can include a plurality of row lines consisting of a plurality of subpixels arranged in a first direction X and a plurality of column lines consisting of a plurality of subpixels arranged in a second direction Y. The display panel 100 can include a plurality of signal lines including a plurality of gate lines, a plurality of data lines, a plurality of power lines, and the like connected to a plurality of subpixels. The first direction X and the second direction Y may be perpendicular to each other.

The display driving circuit 200 can include a data driver that supplies a data signal to a plurality of data lines of the display panel 100, a gate driver that supplies a gate signal to a plurality of gate lines, and a timing controller that controls the operation of the data driver and the gate driver.

The touch sensing circuit 300 can include a touch driving circuit that supplies a touch driving signal to a touch sensor array embedded into the display panel 100, receives a readout signal from the touch sensor array to generate sensing data, and a touch controller that detects the presence or absence of a touch and a touch coordinate position based on the sensing data supplied from the touch driving circuit, and the like.

The touch sensor array can be a self-capacitance method that senses a change in self-capacitance according to a touch, or a mutual-capacitance method that senses a change in mutual-capacitance according to a touch.

The plurality of pixels of the display panel 100 can include a first pixel PX1 and a second pixel PX2 having different light emitting area arrangements of at least one subpixel among the plurality of subpixels.

Each of the first pixel PX1 and the second pixel PX2 can include a plurality of subpixels having different emission colors of the light emitting element. The plurality of subpixels can include a first subpixel including a first color light emitting element, a second subpixel including a second color light emitting element, and a third subpixel including a third color light emitting element. The first to third color light emitting elements can be red, green, and blue light emitting elements, but are not limited thereto. The plurality of subpixels can further include a fourth subpixel including a white light emitting element.

In the first pixel PX1 and the second pixel PX2, the light emitting areas EAk1 and EAk2 of each subpixel can have a stripe shape including a long side in the first direction X and a short side in the second direction Y, but are not limited thereto and can have various shapes.

In each of the first pixel PX1 and the second pixel PX2 according to an embodiment, the light emitting areas EAk1 and EAk2 of at least one color can have an arrangement structure shifted in the first direction X or in an opposite direction from the first direction X of each pixel area.

Accordingly, the light emitting areas EAk1 and EAk2 adjacent to each other in the first direction X in the first and second pixels PX1 and PX2 (N−1th and Nth pixels, N is an integer equal to or greater than two) can have a maximum interval in the first direction X, and the light emitting areas EAk2 and EAk1 can have a minimum interval in the first direction X in the second and first pixels PX2, PX1 (Nth and N+1th pixels). In an embodiment, the light emitting areas EAk1 and EAk2 among the plurality of light emitting areas of each pixel can have the largest light emitting area in the first direction X.

In the pixel array of the display panel 100, the first pixel PX1 and the second pixel PX2 can be alternately disposed along the first direction X in the first pixel line in the first direction X, and in the second pixel line adjacent to the first pixel line in the second direction Y, the second pixel PX2 and the first pixel PX1 can be alternately disposed along the first direction X. In the display panel 100 according to an embodiment, the light emitting areas EAk1 and EAk2 arranged in the first direction X can be disposed such that a maximum interval and a minimum interval alternates, and positions in the first direction X can be alternately disposed along the second direction Y.

Accordingly, in the display panel 100 according to an embodiment since the light emitting areas EAk2 and EAk1 in the first direction X can be formed by any one opening OA of the mask, the minimum interval between the light emitting areas EAk2 and EAk1 can be smaller than the dead zone, which is the minimum gap margin between the openings OA of the mask.

Accordingly, the display panel 100 according to an embodiment can overcome the dead zone limit of the mask, improve the aperture ratio of the light emitting areas EAk1 and EAk2, and improve luminance according to the aperture ratio.

Referring to FIG. 2, the display panel 100 according to an embodiment can include a pixel array 140 having a circuit element layer 120 including a plurality of transistors and a plurality of signal lines disposed on the substrate 110, and a light emitting element layer 130 including a plurality of light emitting elements EL disposed on the circuit element layer 120, and an encapsulation layer 150 disposed on the pixel array 140 to seal the light emitting element layer 130. The display panel 100 can include a touch sensor array 160 including a plurality of sensor electrodes disposed on the encapsulation layer 150, and a light control array 170 including a plurality of light control elements L disposed on the touch sensor array 160 to control a viewing angle. The touch sensor array 160 according to an embodiment can include a sensor electrode, a bridge, and a black matrix disposed to overlap the non-emission area of the light emitting element EL. The display panel 100 can further include a cover substrate 190 coupled to the light control array 170 by an optical clear adhesive (OCA) 180.

The display panel 100 according to an embodiment can include a viewing angle cut-off function that limits a viewing angle in any one of the first and second directions X and Y to within a cut-off angle using the light control elements L that control the viewing angle.

The light control element L can emit light having a first viewing angle by limiting the path of light emitted from the light emitting element EL to be within a specific cut-off angle in the second direction Y, and can emit light having a second viewing angle wider than the first viewing angle because it is not limited to be within a specific angle in the first direction X.

The first viewing angle can be expressed as a narrow viewing angle, and the second viewing angle can be expressed as a wide viewing angle. The light control array 170 can be expressed as a light cutting film (LCF) limiting a viewing angle in the second direction Y.

The first direction X can represent a left-right direction (e.g., horizontal direction) of the display panel 100, a second direction Y can represent an up-down direction (e.g., vertical direction) of the display panel 100, and a third direction Z can represent a front-rear direction (e.g., thickness direction) of the display panel 100. The third direction Z may be perpendicular to each of the first direction X and the second direction Y.

The display panel 100 according to an embodiment can provide an image displayed on the display area DA within a first viewing angle range by limiting a viewing angle with respect to the second direction Y to within a cut-off angle, and within a second viewing angle range with respect to the first direction X within a second viewing angle range wider than the first viewing angle.

Accordingly, when the display apparatus 1000 according to an embodiment is applied to a vehicle, an image displayed on the display apparatus 1000 is blocked from traveling to the front glass of the vehicle located in the second direction Y, thereby preventing the reflected light from interfering with the driver's front view. In an embodiment, the display apparatus 1000 can be applied to a display apparatus for a vehicle disposed on a vehicle dashboard. The display apparatus for a vehicle can include a cluster, a center information display (CID), a co-driver display (CDD), and the like.

The display apparatus 1000 according to an embodiment can be applied not only to a display apparatus for an automobile, but also to various display apparatus such as a mobile display, an IT display, and a TV display requiring viewing angle limitation for privacy and information protection.

Referring to FIG. 3, each subpixel SP can include a light emitting element EL and a pixel circuit 10 driving the light emitting element EL, and a light control element L (see FIG. 2) for controlling a viewing angle can be overlapped on the light emitting element EL.

The subpixel SP according to an embodiment can receive the data voltage Vdata from the data driver of the display driving circuit 200 through any one data line 22. The subpixel SP can receive the scan signal SCAN from the gate driver of the display driving circuit 200 through at least one gate line 12, and can receive the emission control signal EM through at least one gate line 16. The subpixel SP according to an embodiment can receive the high potential power voltage ELVDD from the power management circuit through the first power line 32, receive the low potential power voltage ELVSS through the common (cathode) electrode CE and the second power line 34, and receive the reference voltage Vref through the reference line 24.

The gate driver can be embedded and disposed in the non-display area NDA of the display panel 100, but it is not limited thereto, can be distributed and disposed in the display area DA. The gate driver according to an embodiment can be embedded in the display panel 100 in a gate in panel (GIP) type consisting of transistors formed in the same process as transistors of the display area DA.

The gate driver can include at least one scan driver 210 driving at least one gate line 12 and at least one emission control driver 220 driving at least one gate line 16. The number of gate lines connected to the subpixel SP, the number of scan drivers 210, and the number of emission control drivers 220 can be variously changed according to a detailed configuration of a pixel circuit constituting the subpixel SP.

The scan driver 210 can generate and supply at least one scan signal SCAN to at least one gate line 12 disposed in each of the plurality of pixel row lines.

The emission control driver 220 can generate and supply at least one emission control signal EM to at least one gate line 16 disposed in each of the plurality of pixel row lines.

At least one of an LTPS transistor using a low temperature polysilicon (LTPS) semiconductor and an oxide transistor using a metal-oxide semiconductor can be applied to a plurality of transistors disposed in the display area DA of the display panel 100 and the non-display area NDA including the gate driver. The display panel 100 according to an embodiment can be configured such that an LTPS transistor and an oxide transistor coexist to reduce power consumption.

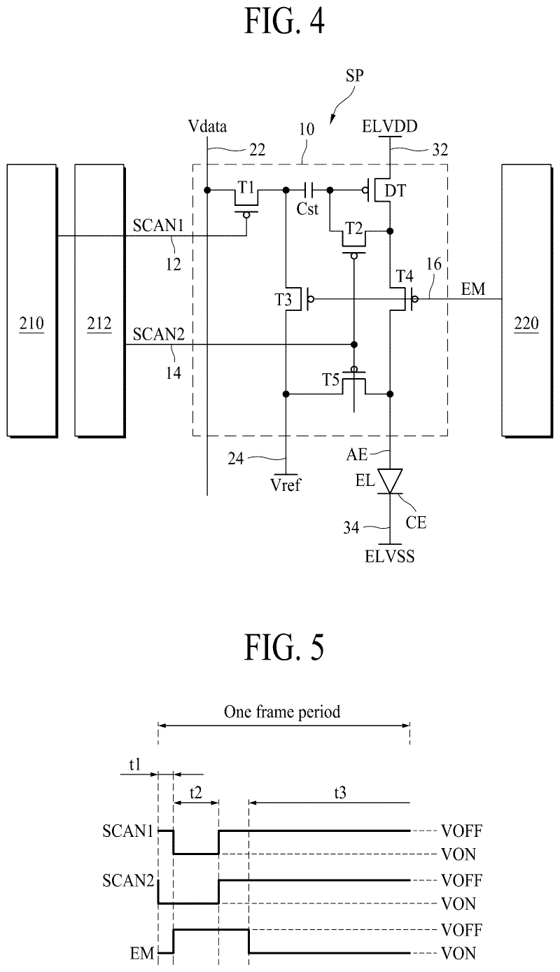

FIG. 4 is an equivalent circuit diagram illustrating an example of a configuration of a subpixel according to an embodiment of the present disclosure, and FIG. 5 is a diagram illustrating an example of a driving waveform of a subpixel according to an embodiment of the present disclosure.

Referring to FIG. 4, the subpixel SP can include a light emitting element EL and a pixel circuit 10 driving the light emitting element EL. In an embodiment, the pixel circuit 10 can include a driving transistor DT, a plurality of switching transistors T1 to T5, and a storage capacitor Cst, but is not limited thereto.

The pixel circuit 10 can receive the first scan signal SCAN1 from the first scan driver 210 through the first gate line 12, and can receive the second scan signal SCAN2 from the second scan driver 212 through the second gate line 14.

The pixel circuit 10 can receive the emission control signal EM from the emission control driver 220 through the third gate line 16.

The pixel circuit 10 can receive the data signal Vdata from the data driver of the display driving circuit 200 (see FIG. 1) through the data line 22. The pixel circuit 10 can receive the high potential power voltage ELVDD from the power management circuit of the display driving circuit 200 (see FIG. 1) through the first power line 32, receive the low potential power voltage ELVSS through the second power line 34 and the common (cathode) electrode CE, and receive the reference voltage Vref through the reference line 24.

Referring to FIG. 5, each frame period for driving the subpixel SP can include an initialization period t1, a sampling and writing period t2, and an emission period t3.

Each of the driving transistor DT and the plurality of switching transistors T1 to T5 of the pixel circuit 10 includes a gate electrode, a source electrode, and a drain electrode. Since the source electrode and the drain electrode are not fixed and can be changed according to the voltage and current direction applied to the gate electrode, one of the source electrode and the drain electrode can be expressed as the first electrode, and another one of the source electrode and the drain electrode can be expressed as the second electrode. The driving transistor DT and the plurality of switching transistors T1 to T5 of the pixel circuit 10 can use at least one of a polysilicon semiconductor, an amorphous silicon semiconductor, and an oxide semiconductor, and can use the P type or the N type and can be used in combination of the P type and the N type.

The light emitting element EL can include an anode electrode AE connected to the fourth switching transistor T4, a cathode electrode CE connected to a second power line 34 supplying a low potential power voltage ELVSS, and a light emitting layer between the anode electrode AE and the cathode electrode CE. In the light emitting element EL, when a driving current is supplied from the driving transistor DT through the fourth switching transistor T4, electrons from the cathode electrode CE are injected into the light emitting layer, and holes from the anode electrode AE are injected into the light emitting layer to emit light having a brightness proportional to the current value of the driving current by recombination of electrons and holes in the light emitting layer.

The gate electrode of the driving transistor DT can be connected to the storage capacitor Cst, the first electrode can be connected to the first power line 32 supplying the high potential power voltage ELVDD, and the second electrode can be connected to the first electrode of the fourth switching transistor T4. The driving transistor DT can be connected to the light emitting element EL through the fourth switching transistor T4, and can drive the light emitting element EL through the fourth switching transistor T4. The driving transistor DT can control the light emission intensity of the light emitting element EL through the fourth switching transistor T4 by controlling the driving current according to the driving voltage charged in the storage capacitor Cst.

The storage capacitor Cst can be connected between the second electrode of the first switching transistor T1 and the gate electrode of the driving transistor DT to charge a driving voltage corresponding to the data voltage Vdata. The storage capacitor Cst can hold the charged driving voltage during the light emission period t3 during which the first switching transistor T1 is turned off, and supply the driving voltage to the driving transistor DT.

The first switching transistor T1 can be turned on or turned off in response to the first scan signal SCAN1 of the first gate line 12 disposed in the i-th (i is a natural number) pixel row line. The first switching transistor T1 can supply the data voltage Vdata supplied through the data line 22 to the first electrode of the storage capacitor Cst during the sampling and writing period t2 in which the first scan signal SCAN1 has the gate-on voltage VON. The switching transistor T1 can be turned off during the initialization period t1 and the light emission period t3 in which the first scan signal SCAN1 has the gate-off voltage VOFF.

The second and fifth switching transistors T2 and T5 can be turned on or off in response to the second scan signal SCAN2 supplied to the second gate line 14 of the i-th pixel row line. The second and fifth switching transistors T2 and T5 can be turned on during the initialization period t1 and the sampling and writing period t2 in which the second scan signal SCAN2 has the gate-on voltage VON, and can be turned off during the light emission period t3 in which the second scan signal SCAN2 has the gate-off voltage VOFF.

The second switching transistor T2 can connect the driving transistor DT in a diode structure by connecting the gate electrode of the driving transistor DT to the second electrode during the initialization period t1 and the sampling and writing period t2 in response to the second scan signal SCAN2. The second switching transistor T2 can compensate the threshold voltage Vth of the driving transistor DT by charging the threshold voltage Vth of the driving transistor DT to the storage capacitor Cst. Accordingly, the storage capacitor Cst can be charged with the data voltage compensated for the threshold voltage Vth of the driving transistor DT.

The fifth switching transistor T5 can supply the reference voltage Vref supplied through the reference line 24 to the anode electrode AE of the light emitting element EL during the initialization period t1 and the sampling and writing period t2 in response to the second scan signal SCAN2.

The third and fourth switching transistors T3 and T4 can be turned on or turned off in response to the light emission control signal EM supplied to the third gate line 16 of the i-th pixel row line. The third and fourth switching transistors T3 and T4 can be turned on during the initialization period t1 and the light emission period t3 in which the light emission control signal EM has the gate-on voltage VON. The third and fourth switching transistors T3 and T4 can be turned off during the sampling and writing period t2 and a period between the sampling and writing period 42 and the light emission period t3 in which the light emission control signal EM has the gate-off voltage VOFF.

The third switching transistor T3 can supply the reference voltage Vref supplied through the reference line 24 to the first electrode of the storage capacitor Cst during the initialization period t1 and the light emission period t3 in response to the light emission control signal EM.

The fourth switching transistor T4 can connect the driving transistor DT to the light emitting element EL during the initialization period t1 and the light emission period t3 in response to the light emission control signal EM.

During the light emission period t3 of each frame period, the driving transistor DT can drive the light emitting element EL through the fourth switching transistor T4.

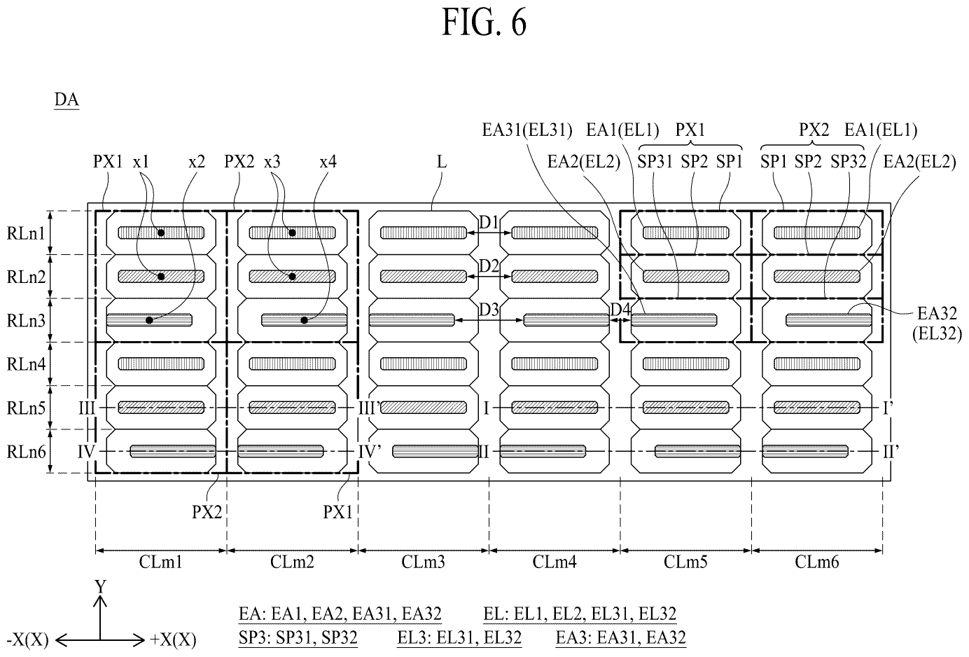

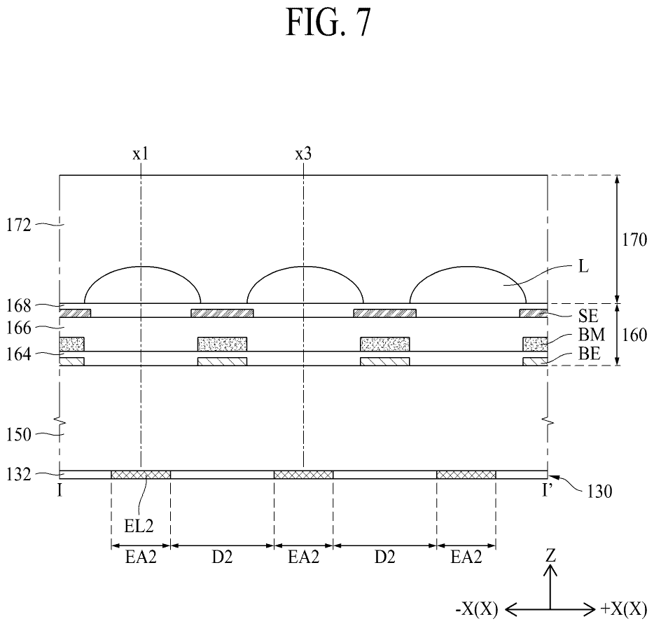

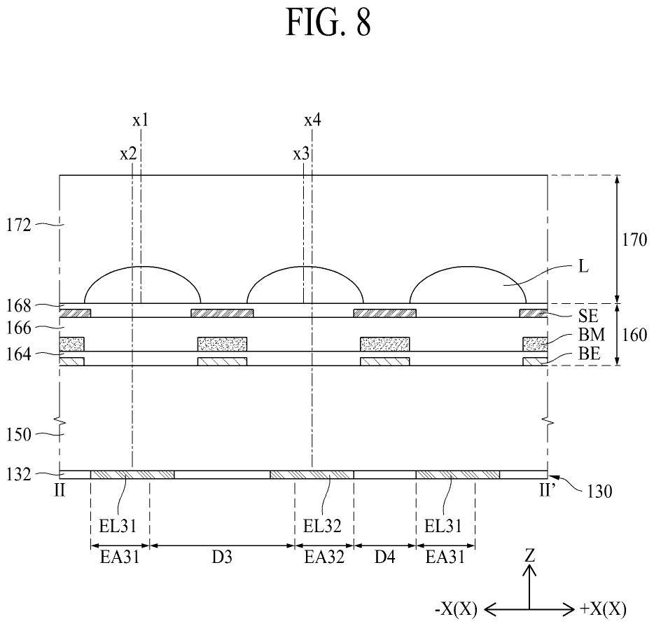

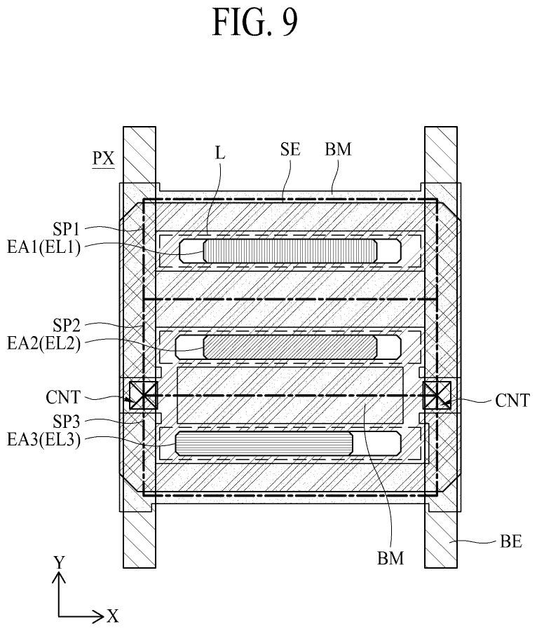

FIG. 6 is an enlarged plan view illustrating an example of a plurality of pixel areas or light emitting areas of a display apparatus according to an embodiment of the present disclosure. FIGS. 7 and 8 are respectively a cross-sectional view schematically illustrating examples of structures of a plurality of second subpixel regions taken along line I-I′ and a cross-sectional view schematically illustrating structures of a plurality of third subpixel regions taken along line II-II′ in FIG. 6. FIG. 9 is an enlarged plan view illustrating an example of a pixel area or light emitting areas according to an embodiment of the present disclosure.

The display panel 100 according to an embodiment includes a plurality of pixel areas or light emitting areas, and for convenience of description, FIG. 6 shows a plurality of subpixel arrangement structure constituting a plurality of row lines RLn1 to RLn6 and a plurality of column lines CLm1 to CLm6. Each subpixel may include one light emitting element, each light emitting element may include one light emitting area.

Referring to FIG. 6, the display area DA of the display panel 100 can include a pixel array in which a plurality of pixels PX1 and PX2 are arranged in a matrix form. The plurality of pixels PX1 and PX2 includes the first pixel PX1 and the second pixel PX2 having the different arrangement structure of the light emitting area EA3: EA31 and EA32 of at least one subpixel SP3: SP31 and SP32 of the plurality of the subpixels SP1, SP2 and SP3.

The first pixel PX1 and the second pixel PX2 can be alternately disposed along the first direction X and can be alternately disposed along the second direction Y.

The first pixel PX1 and the second pixel PX2 can be arranged to repeat the order of the first pixel PX1 and the second pixel PX2 along the first direction X in any one of two pixel lines adjacent to each other in the second direction Y, and can be arranged to repeat the order of the second pixel PX2 and the first pixel PX1 along the first direction X in another pixel line. The first pixel PX1 and the second pixel PX2 can be arranged to repeat the order of the first pixel PX1 and the second pixel PX2 along the second direction Y in any one of the two pixel lines adjacent to each other in the first direction X, and can be arranged to repeat the order of the second pixel PX2 and the first pixel PX1 along the first direction X in another pixel line.

A pixel group including the first and second pixels PX1 and PX2 adjacent to each other in the first direction X, the second pixel PX2 adjacent to the first pixel PX1 in the second direction Y, and the first pixel PX1 adjacent to the second pixel PX2 in the second direction Y can be repeatedly disposed in the first direction X and the second direction Y.

Each of the first pixel PX1 and the second pixel PX2 can include a plurality of subpixels SP1, SP2, and SP3 having different emission colors of the light emitting elements EL1, EL2, and EL3. A plurality of subpixels SP1, SP2, and SP3 can include a first subpixel SP1 including a first color light emitting element EL1, a second subpixel SP2 including a second color light emitting element EL2, and a third subpixel SP3 including a third color light emitting element EL3. The first to third color light emitting elements EL1, EL2, and EL3 can be red, green, and blue light emitting elements, but are not limited thereto.

In each of the first pixel PX1 and the second pixel PX2, a plurality of light emitting elements EL1, EL2, and EL3 of each of the plurality of subpixels SP1, SP2, and SP3 can be disposed in parallel in the second direction Y, and light emitting elements of the same color can be aligned and disposed in the first direction X.

In the light emitting areas EA1, EA2, and EA3 of the light emitting elements EL1, EL2, and EL3 of the plurality of subpixels SP1, SP2, and SP3, light emitting areas of same colors can be arranged along the first direction X and the light emitting area EA1, EA2, and EA3 of different colors can be arranged along the second direction Y.

In an embodiment, the first row line RLn1 or the fourth row line RLn4 can include a plurality of first subpixels SP1 in which a plurality of first light emitting areas EA1 are arranged along the first direction X. The second row line RLn2 or the fifth row line RLn5 can include a plurality of second subpixels SP2 in which a plurality of second light emitting areas EA2 are arranged along the first direction X. The third row line RLn3 can include a plurality of 3-1 subpixels SP31 and 3-2 subpixels SP32 in which the 3-1 light emitting area EA31 and the 3-2 light emitting area EA32 are alternately arranged along the first direction X. The sixth row line RLn6 can include a plurality of 3-2 subpixels SP32 and 3-1 subpixels SP31 in which the 3-2 light emitting area EA32 and the 3-1 light emitting area EA31 are alternately arranged along the first direction X opposite to the third row line RLn3.

In an embodiment, each of the odd-numbered column lines CLm1, CLm3, and CLm5 can include a plurality of first to third subpixels SP1, SP2, SP31, and SP32 in which the first to 3-1 light emitting areas EA1, EA2, and EA31 and the first to 3-2 light emitting areas EA1, EA2 and EA32 are alternately arranged along the second direction Y. In an embodiment, each of the even-numbered column lines CLm2, CLm4, and CLm6 can include a plurality of first to third subpixels SP1, SP2, SP32, and SP31 in which the first to 3-2 light emitting areas EA1, EA2, and EA32 and the first to 3-1 light emitting areas EA1, EA2 and EA31 are alternately arranged along the second direction Y.

Each of the light emitting areas EA1, EA2, and EA3 of a plurality of subpixels SP1, SP2, and SP3 can include a long side in the first direction X and a short side in the second direction Y. A plurality of light emitting areas EA1, EA2, and EA3 can have different or the same light emitting area for each color, or the light emitting area of at least one color can be different from the light emitting area of another color.

In an embodiment, the first light emitting area EA1 can be smaller than or the same as the second light emitting area EA2. Third light emitting areas EA3: EA31 and EA32 can have the largest light emitting area. In an embodiment, the first and second light emitting areas EA1 and EA2 can have the same long side length in the first direction X, and the third light emitting area EA3 can have the largest long side length in the first direction X. In an embodiment, a plurality of light emitting areas EA1, EA2, and EA3 can have the same short side length in the second direction Y.

A light control element L can overlap on a plurality of light emitting areas EA1, EA2, and EA3 of the first pixel PX1 and the second pixel PX2. The light incident surface of the light control element L can include a long side in the first direction X and a short side in the second direction Y.

In an embodiment, the light control element L can have a half-cylindrical lens structure long in the first direction X, but is not limited thereto.

The light control elements L disposed on each of the plurality of light emitting areas EA1, EA2, and EA3 can have the same light incident surface size, or can have different light incident surface sizes according to the light emitting areas of the light emitting areas EA1, EA2, and EA3. The size of the light incident surface of the light control element L can be set to be larger than the light emitting area of each of the plurality of light emitting areas EA1, EA2, and EA3, thereby improving light emission efficiency.

In the first pixel PX1, the first light emitting area EA1 and the second light emitting area EA2 can be aligned and disposed at the same first center point x1 in the second direction Y, and the 3-1 light emitting area EA31 can be aligned and disposed at the second center point x2 shifted in the 1-1 direction −X from the first center point x1. The light control elements L disposed on a plurality of light emitting areas EA1, EA2, and EA31 of the first pixel PX1 can be aligned and disposed at the first center point x1. In the first pixel PX1, the center point x2 of the 3-1 light emitting area EA31 can be shifted from the center point x1 of the light control element L in the 1-1 direction-X.

In the second pixel PX2, the first light emitting area EA1 and the second light emitting area EA2 can be aligned and disposed at the same third center point x3 in the second direction Y, and the 3-2 light emitting area EA32 can be aligned and disposed at the fourth center point x4 shifted in the 1-2 direction +X from the third center point x3. The light control elements L disposed on a plurality of light emitting areas EA1, EA2, and EA32 of the second pixel PX2 can be aligned and disposed at the third center point x3. In the second pixel PX2, the center point x4 of the 3-2 light emitting area EA32 can be shifted from the center point x3 of the light control element L in the 1-2 direction +X.

Accordingly, the first light emitting areas EA1 adjacent to each other in the first direction X in the first pixel PX1 and the second pixel PX2 can have a first distance D1, and the second light emitting areas EA2 adjacent to each other in the first direction X can also have a second distance D2 equal to or similar to the first distance D1.

In the first pixel PX1 (N−1th pixel) and the second pixel PX2 (Nth pixel) adjacent to each other in the first direction X, the third light emitting areas EA31 and EA32 can have a third distance D3. In the second pixel PX2 (Nth pixel) and the first pixel PX1 (N+1th pixel) adjacent to each other in the first direction X, the third light emitting areas EA32 and EA31 can have a fourth distance D4. The third distance D3 can be greater than or equal to the first and second distances D1 and D2, and can be greater than the fourth distance D4. The fourth distance D4 can be less than the first and second distances D1 and D2. The third distance D3 can be a maximum interval in the pixel array, and the fourth distance D4 can be a minimum interval in the pixel array.

In the display panel 100 according to an embodiment, a plurality of third light emitting areas EA31 and EA32 aligned in the first direction X can be alternately disposed to have a third distance D3, or the maximum interval, and a fourth distance D4, or a minimum interval, and can be disposed in a zigzag shape with different positions in the first direction X along the second direction Y.

Accordingly, since the light emitting areas EA31 and EA32 having the minimum interval D4 in the first direction X can be formed through any one opening OA of the mask, the minimum interval D4 between the light emitting areas EA31 and EA32 can be smaller than the dead zone between the openings OA of the mask. Accordingly, it is possible to overcome the dead zone limit of the mask and improve the aperture ratio of the light emitting areas EA31 and EA32 having the largest light emitting area and improve the luminance.

Referring to FIGS. 7 and 8, a plurality of second light emitting elements EL2 arranged in the first direction X in the light emitting element layer 130 of the pixel array can include a plurality of second light emitting areas EA2 having a second distance D2 by the bank insulating layer 132. A plurality of third light emitting elements EL31, EL32, and EL31 arranged in the first direction X in the light emitting element layer 130 can include a 3-1 light emitting area EA31, a 3-2 light emitting area EA32 having a third distance D3 from the 3-1 light emitting area EA31 by the bank insulating layer 132, and a 3-1 light emitting area EA31 having a fourth distance D4 from the 3-2 light emitting area EA32 by the bank insulating layer 132.

An encapsulation layer 150 can be disposed on the light emitting element layer 130, and a touch sensor array 160 can be disposed on the encapsulation layer 150.

The touch sensor array 160 according to an embodiment is disposed to overlap a non-emission area of the pixel array, for example, a non-emission area except for the light emitting areas EA: EA1, EA2, EA31, and EA32 of the subpixels SP1, SP2, SP31, and SP32, and can include a bridge electrode BE, a black matrix BM, and a sensor electrode SE stacked with at least one insulating layer interposed therebetween on the encapsulation layer 150. The bridge electrode BE, the black matrix BM, and the sensor electrode SE can be disposed in a non-emission area to serve as a barrier that blocks light. In an embodiment, the sensor electrode SE and the black matrix BM can be overlapped and disposed in a non-emission area surrounding the light emitting area EA of the pixel array.

Referring to FIGS. 7 to 9, the bridge electrode BE disposed to overlap the non-emission area of the subpixels SP1, SP2, SP31, and SP32 can be electrically connected to the sensor electrode SE through the contact part CNT. In the contact part CNT, the sensor electrode SE can be connected to the bridge electrode BE through a contact hole penetrating a plurality of touch insulating layers 166 and 164. The black matrix BM may not overlap the contact part CNT.

In an embodiment, the contact part CNT can be disposed in a non-emission area between the second subpixel SP2 and the third subpixel SP3 adjacent to each other in the second direction Y. In an embodiment, the contact part CNT can be disposed in a non-emission area disposed diagonally with the second light emitting area EA2 and the 3-1 light emitting area EA31 among non-emission areas between the second subpixel SP2 and the 3-1 subpixel SP31 adjacent to each other in the second direction Y.

The bridge electrode BE can be disposed on the encapsulation layer 150 and the black matrix BM can be disposed on the bridge electrode BE with any one touch insulating layer 164 interposed therebetween. The sensor electrode SE can be disposed on the black matrix BM with any one touch insulating layer 166 interposed therebetween. Any one touch insulating layer 168 can be disposed on the sensor electrode SE.

The sensor electrode SE overlapping the non-emission areas of the subpixels SP1, SP2, SP31, and SP32 can have openings overlapping the light emitting areas EA: EA1, EA2, EA31, and EA32 of the light emitting elements EL: EL1, EL2, EL31, and EL32, and the light control element L.

In an embodiment, the end portion of the opening of the sensor electrode SE can overlap the end portion in the second direction Y of the light incident surface of the light control element L, and can further overlap the end portion in the first direction X. In an embodiment, the overlapping portion of the sensor electrode SE and the light control element L can be disposed adjacent to the light emitting areas EA1, EA2, EA31, and EA32 in the second direction Y to limit the radiation angle of light emitted from the light emitting areas EA: EA1, EA2, EA31, and EA32 to within the first cut-off angle (first viewing angle) in the second direction Y and can block light leakage. In an embodiment, the overlapping portion of the sensor electrode SE and the light control element L can be spaced apart from the light emitting areas EA: EA1, EA2, EA31, and EA32 in the first direction X to control the radiation angle of light emitted from the light emitting areas EA: EA1, EA2, EA31, and EA32 to be within the second cut-off angle (second viewing angle) greater than the first cut-off angle (first viewing angle) in the first direction X and block light leakage.

The black matrix BM overlapping the non-emission areas of the subpixels SP1, SP2, SP31, and SP32, can include openings that overlap the light emitting areas EA: EA1, EA2, EA31 and EA32 of the light emitting elements EL: EL1, EL2, EL31, and EL32 and the light control element L. The size of the opening of the sensor electrode SE can be smaller or larger than the size of the opening of the black matrix BM. In an embodiment, an end portion of the opening of the black matrix BM may not overlap the light incident surface of the light controlling element L.

The bridge electrode BE overlapping the non-emission areas of the subpixels SP1, SP2, SP31, and SP32 can include openings overlapping the light emitting areas EA: EA1, EA2, EA31, and EA32 of the light emitting elements EL: EL1, EL2, EL31, and EL32, and the light control element L. A plurality of bridge electrodes BE can extend in the second direction Y, and the openings of the bridge electrodes BE can be disposed between a plurality of bridge electrodes BE adjacent to each other in the first direction X. The bridge electrode BE overlapping the black matrix BM can have a smaller line width in the first direction X than the black matrix BM.

A light control array 170 including a plurality of light control elements L can be disposed on the touch sensor array 160. The plurality of light control elements L can be disposed to individually overlap the light emitting areas EA: EA1, EA2, EA31, and EA32 of a plurality of light emitting elements EL: EL1, EL2, EL31, and EL32. The light control array 170 can further include a protective layer 172 covering the light control elements L disposed on the touch sensor array 160.

In an embodiment, each center points x1 and x3 in the first direction X of the light control element L can be aligned with the center points in the first direction X of the light emitting areas EA1 and EA2.

The plurality of the first light emitting area EA1 can be disposed at the same distance D1 along the first direction X, and the plurality of the second light emitting areas EA2 can be disposed at the same distance D2 along the first direction X.

In an embodiment, the center point x2 in the first direction X of the 3-1 light emitting area EA31 can be shifted from the center point x1 in the first direction X in the area of the light control element L to the 1-1 direction −X. The center point x4 in the first direction X of the 3-2 light emitting area EA32 can be shifted from the center point x3 in the first direction X in the area of the light control element L to the 1-2 direction +X. A plurality of third light emitting areas EA31 and EA32 can be alternately disposed to have a third distance D3 (a maximum interval) and a fourth distance D4 (a minimum interval) along the first direction X.

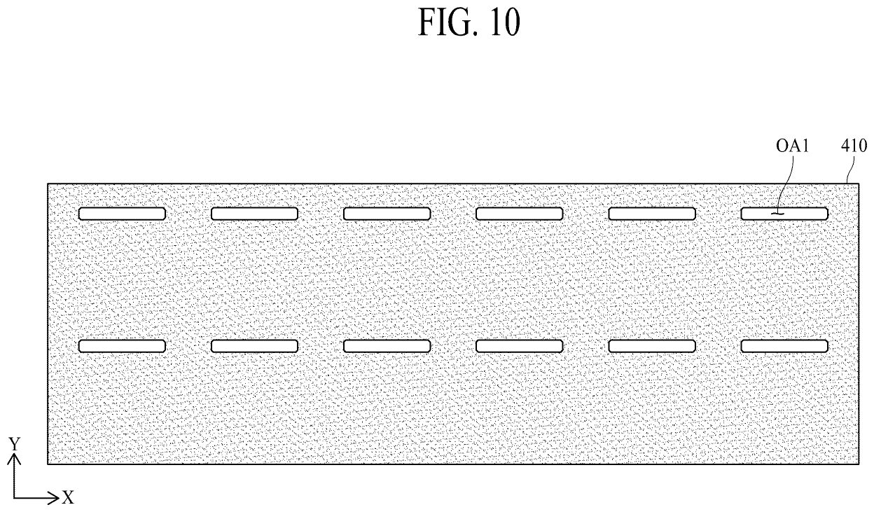

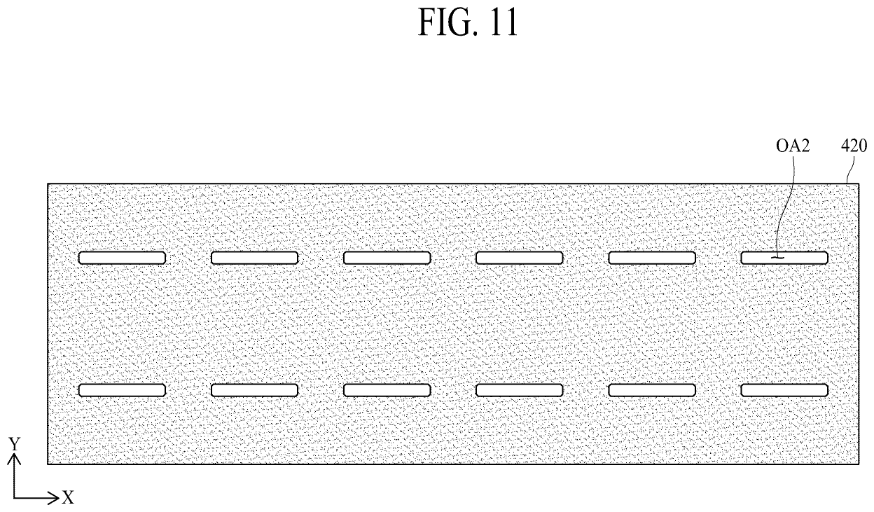

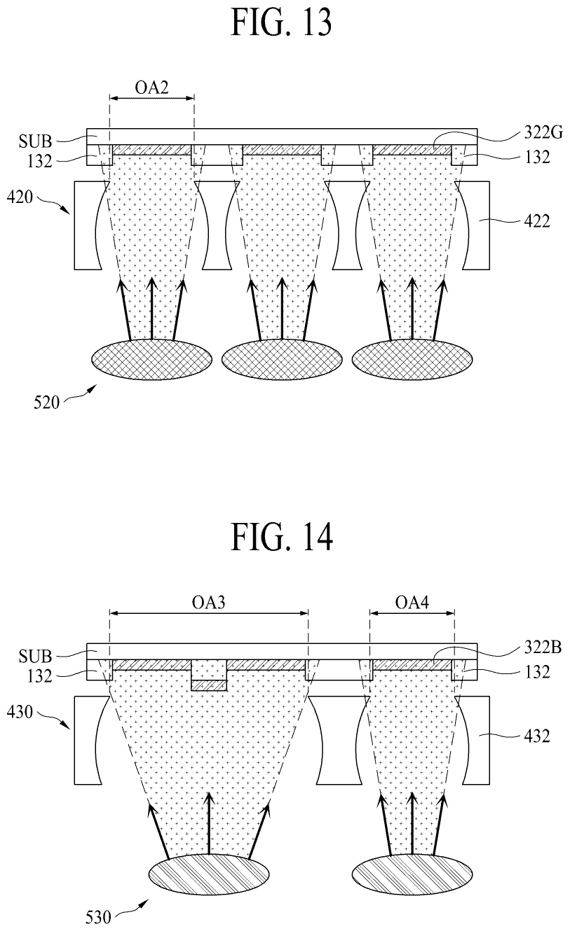

FIGS. 10 to 12 are a plan view illustrating examples of a first to a third mask according to an embodiment of the present disclosure. FIG. 13 is a schematic diagram schematically illustrating an example of a method of depositing a second light emitting layer of a display apparatus according to an embodiment of the present disclosure. FIG. 14 is a schematic diagram schematically illustrating an example of a method of depositing a third light emitting layer of a display apparatus according to an embodiment of the present disclosure.

Referring to FIGS. 10 to 12, the first to third masks 410, 420, and 430 according to an embodiment can be fine metal masks (FMM).

Referring to FIGS. 6 and 10, a plurality of first light emitting elements EL1 can include a first light emitting layer deposited in a pattern shape in a plurality of first light emitting areas EA1 through the first opening OA1 of the first mask 410. The first opening OA1 of the first mask 410 can overlap the first light emitting area EA1, and the first opening OA1 can have an area larger than the first light emitting area EA1. A plurality of first light emitting areas EA1 can be disposed in the first direction X with a first distance D1.

Referring to FIGS. 6, 11, and 13, a plurality of second light emitting elements EL2 can include a second light emitting layer 322G deposited in a pattern shape in a plurality of second light emitting areas EA2 through the second opening OA2 of the second mask 420. The second opening OA2 of the second mask 420 can overlap the second light emitting area EA2, and the second opening OA2 can have an area larger than the second light emitting area EA2. A plurality of second light emitting areas EA2 can be disposed with a second distance D2 in the first direction X.

The deposition source 520 can eject the deposition vapor by evaporating the second light emitting material, and the ejected deposition vapor can pass through the second opening OA2 between the ribs 422 of the second mask 420 and be deposited on the work substrate SUB in a pattern shape to form a second light emitting layer 322G. The work substrate SUB can be a substrate in an intermediate stage in which an anode electrode and a bank insulating layer 132 are disposed on the circuit element layer 120 of the substrate 110. A spacer supporting the ribs 422 of the mask 420 can be further disposed on the bank insulating layer 132.

Referring to FIGS. 6, 12, and 14, a plurality of 3-2 and 3-1 light emitting elements EL32 and EL31 can include a third light emitting layer 322B deposited in a pattern shape in the 3-2 and 3-1 light emitting areas EA32 and EA31 through the third opening OA3 of the third mask 430. The third opening OA3 of the third mask 430 can overlap the 3-2 and 3-1 light emitting areas EA32 and EA31 adjacent to each other in the first direction X, and the third opening OA3 can have an area larger than an integrated area of the 3-2 and 3-1 light emitting areas EA32 and EA31. The third opening OA3 can be expressed as an integrated opening.

The deposition source 530 can eject the deposition vapor by evaporating the third light material, and the ejected deposition vapor can pass through the third opening OA3 between the ribs 432 of the third mask 430 and can be deposited on the work substrate SUB in a pattern shape to form the third light emitting layer 322B. The third mask 430 can further include a fourth opening OA4 overlapping any one of the 3-1 and 3-2 light emitting areas EA31 and EA32. The work substrate SUB can be a substrate of an intermediate stage in which an anode electrode and a bank insulating layer 132 are disposed on the circuit element layer 120 of the substrate 110. A spacer supporting the ribs 430 of the mask 430 can be further disposed on the bank insulating layer 132.

The third light emitting layer 322B deposited in the 3-2 and 3-1 light emitting areas EA32 and EA31 through the third opening OA3 of the third mask 430 can also be deposited on the bank insulating layer 132 between the 3-2 and 3-1 light emitting areas EA32 and EA31. Since the third light emitting layer 322B deposited on the bank insulating layer 132 does not contact the anode electrode, the 3-2 and 3-1 light emitting areas EA32 and EA31 can be separated and independently emit light.

As such, according to an embodiment, the 3-2 and 3-1 light emitting areas EA32 and EA31 adjacent to each other in the first direction X can be formed through the integrated opening OA3 of the third mask 430. Accordingly, since the minimum interval D4 between the 3-2 and 3-1 light emitting areas EA32 and EA31 can be smaller than the minimum dead zone margin between the openings OA3 of the mask 430, the dead zone limit of the mask can be overcome, and since the aperture ratio of the light emitting areas EA32 and EA31 having the largest light emitting area in the first direction X can be improved, the luminance can also be improved.

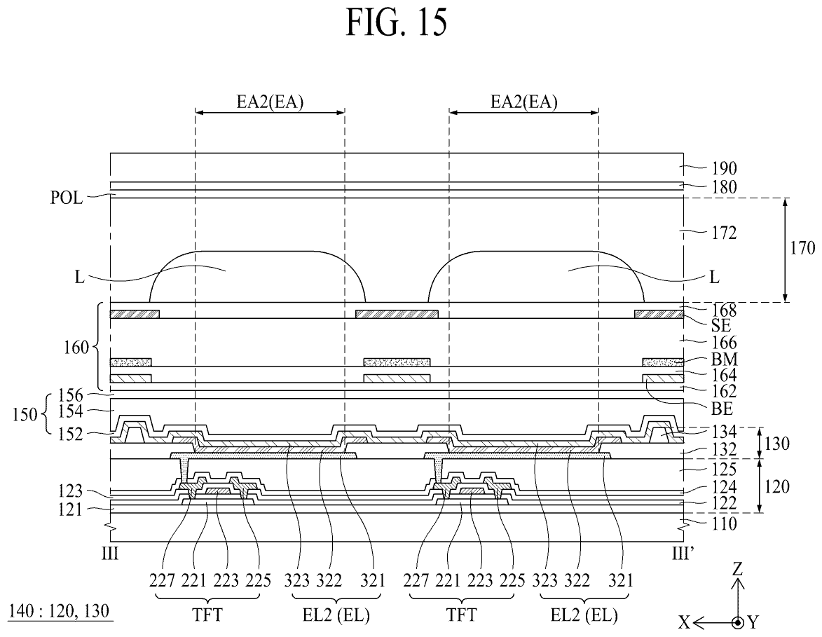

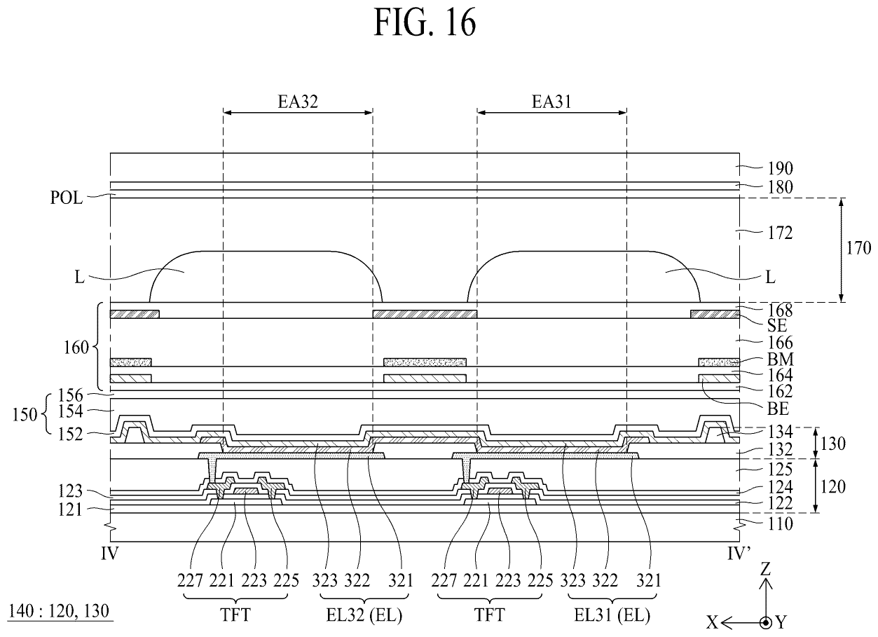

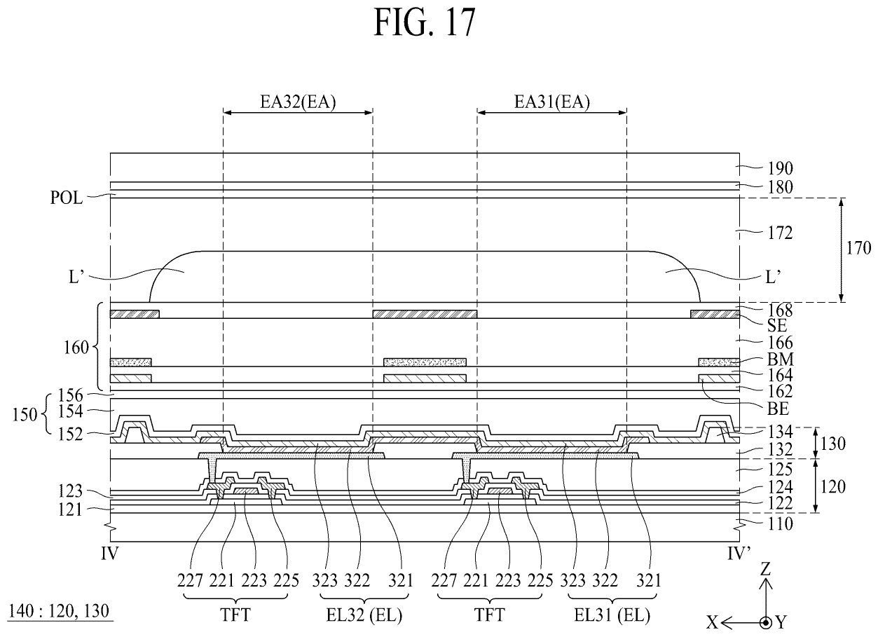

FIGS. 15 and 16 are respectively a cross-sectional view illustrating an example of an overall structure of a second subpixel area taken along a line III-III′ and a cross-sectional view illustrating an example of an overall structure of a third subpixel area along a line IV-IV′ in FIG. 6. FIG. 17 is a cross-sectional view illustrating an example of another structure of a third subpixel region according to an embodiment of the present disclosure.

Referring to FIGS. 15 to 17, the display panel 100 according to an embodiment can include a pixel array 140 including a circuit element layer 120 disposed on the substrate 110 and a light emitting element layer 130 disposed on the circuit element layer 120, the encapsulation layer 150 disposed on the pixel array 140 to seal the light emitting element layer 130, a touch sensor array 160 disposed on the encapsulation layer 150, and a light control array 170 disposed on the touch sensor array 160. The display panel 100 can further include a polarizing plate POL disposed on the light control array 170, an optical clear adhesive OCA 180, a cover substrate 190, and the like.

The substrate 110 can include an insulating material such as glass or plastic. The plastic substrate can be formed of a flexible material. For example, the substrate 110 can include at least one organic insulating material among an acrylic resin, an epoxy resin, a siloxane resin, a polyimide resin, and a polyamide resin.

The circuit element layer 120 according to an embodiment can include a plurality of insulating layers stacked on the substrate 110. For example, a plurality of insulating layers can include a buffer layer 121, a gate insulating layer 122, an interlayer insulating layer 123, a protective layer 124, and a planarization layer 125.

The buffer layer 121 can have a single layer or multilayer structure including an inorganic insulating material such as silicon oxide (SiOx), silicon nitride (SiNx), aluminum oxide (Al₂O₃). The buffer layer 121 can prevent an impurity such as hydrogen from being introduced into the semiconductor layer 221 through the substrate 110.

In an embodiment, the buffer layer 121 can include a multi-buffer layer and an active buffer layer. In this case, a multi-buffer layer can be disposed on the substrate 110 and an active buffer layer can be disposed on the multi-buffer layer. A light blocking layer can be disposed between the multi-buffer layer and the active buffer layer.

A plurality of transistors including the transistor TFT can be disposed on the buffer layer 121. The transistor TFT includes a semiconductor layer 221, a gate electrode 223, a source electrode 225 and a drain electrode 227 disposed on the buffer layer 121. The gate insulating layer 122 is disposed between the semiconductor layer 221 and the gate electrode 223. The interlayer insulating layer 123 is disposed between the gate electrode 223 and the source and drain electrodes 225 and 227. The source electrode 225 and the drain electrode 227 of the transistor TFT can be connected to a source region and a drain region of the semiconductor layer 221, respectively, through contact holes penetrating the interlayer insulating layer 123 and the gate insulating layer 122.

The semiconductor layer 221 can include polycrystalline silicon, or can include an oxide semiconductor material. The semiconductor layer 221 can include low-temperature polysilicon (LTPS). The semiconductor layer 221 can include at least one oxide semiconductor material among an IZO (InZnO)-based, an IGO (InGaO)-based, an ITO (InSnO)-based, an IGZO(InGaZnO)-base, an IGZTO (InGaZnSnO)-based, a GZTO (GaZnSnO)-based, a GZO (GaZnO)-based, and an ITZO (InSnZnO)-based. A light shielding layer can be further disposed under the semiconductor layer 221.

The gate insulating layer 122 can include an inorganic insulating material such as silicon oxide (SiOx) and silicon nitride (SiNx). The gate insulating layer 122 can include a material having a high dielectric constant. For example, the gate insulating layer 122 can include a High-K material such as hafnium oxide (HfO). The gate insulating layer 122 can have a multilayer structure.

The gate electrode 223 and the gate line can be disposed on the gate insulating layer 122.

The interlayer insulating layer 123 can include an inorganic insulating material such as silicon oxide (SiOx) and silicon nitride (SiNx). The interlayer insulating layer 123 can have a multilayer structure.

A source electrode 225 and a drain electrode 227, a data line, and a power line can be disposed on the interlayer insulating layer 123.

The protection layer 124 and the planarization layer 125 can be stacked on the transistors TFT. The protection layer 124 can include an inorganic insulating material such as silicon oxide (SiOx) and silicon nitride (SiNx). The planarization layer 125 can include an organic insulating material different from that of the protection layer 124 and can provide a flat surface. The planarization layer 125 can have a double layer structure.

A light emitting element layer 130 including a plurality of light emitting elements EL: EL2, EL31, and EL32 can be disposed on the planarization layer 125.

Each of the light emitting elements EL can include an anode electrode 321 disposed on the planarization layer 125, a light emitting layer 322 disposed on the anode electrode 321, and a common cathode electrode 323 disposed on the light emitting layer 322.

The anode electrode 321 can be connected to one of the source electrode 225 and the drain electrode 227 of the transistor TFT through a contact hole penetrating the planarization layer 125 and the protective layer 124. The anode electrode 321 can include a conductive material having a high reflectivity. The anode electrode 321 can include a metal such as aluminum (Al), silver (Ag), titanium (Ti), and silver-palladium-copper (APC) alloy. The anode electrode 321 can further include a transparent conductive material such as an indium tin oxide (ITO) or an indium zinc oxide (IZO). In an embodiment, the anode electrode 321 can have a multilayer structure (Ti/Al/Ti) of titanium (Ti) and aluminum (Al), a multilayer structure (ITO/Al/ITO) of ITO and aluminum (Al), or a multilayer structure (ITO/APC/ITO) of ITO and APC.

The light emitting layer 322 can include an emission material layer (EML) including a light emitting material. The light emitting material can include an organic material, an inorganic material, or a hybrid material. The light emitting layer 322 can have a multilayer structure. In an embodiment, the light emitting layer 322 can further include at least one of a hole injection layer (HIL), a hole transport layer (HTL), an electron transport layer (ETL), and an electron injection layer (EIL).

The cathode electrode 323 can be a common electrode and can include a conductive material that transmits light. The cathode electrode 323 can include a transparent conductive material such as ITO or IZO. The cathode electrode 323 can include aluminum (Al), magnesium (Mg), silver (Ag), or an alloy thereof and can have a thin thickness capable of transmitting light.

The anode electrodes 321 of the light emitting element EL can be spaced apart from each other, and the bank insulating layer 132 can be positioned between the anode electrodes 321 of the light emitting element EL. The bank insulating layer 132 can cover the edge of the anode electrode 321. The bank insulating layer 132 can include an opening through which the anode electrode 321 of the light emitting element EL is exposed to define light emitting areas EA: EA2, EA31, and EA32, respectively. The light emitting layer 322 and the cathode electrode 323 can be stacked on the anode electrode 321 exposed by the opening of the bank insulating layer 132.

The bank insulating layer 132 can include an organic insulating material. The bank insulating layer 132 can include an organic material different from that of the planarization layer 125, and can have a single layer or a double layer structure.

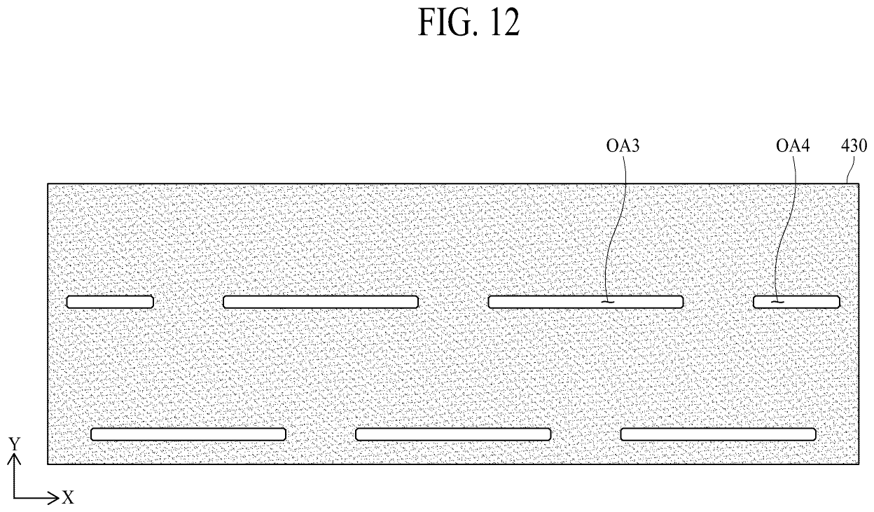

Referring to FIGS. 16 and 17, the 3-2 light emitting element EL32 and the 3-1 light emitting element EL31 adjacent to each other with a minimum interval D4 in the first direction X can include an anode electrode 321 disposed independently in the 3-2 light emitting area EA32 and the 3-1 light emitting area EA31, a light emitting layer 322 disposed on the anode electrode 321 and the bank insulating layer 132 disposed between the anode electrode 321 thereby being interconnected, and a cathode electrode 323 disposed on the light emitting layer 322. The light emitting layer 322 shared by the 3-2 light emitting area EA32 and the 3-1 light emitting area EA31 can be formed through the integrated opening OA3 of the third mask 430 as described in FIG. 12.

A spacer 134 can be further disposed on the bank insulating layer 132. The spacer 134 can support a mask when forming the light emitting layer 322.

The encapsulation layer 150 positioned on the light emitting element layer 130 can prevent damage to the light emitting elements EL due to external moisture and impact. The encapsulation layer 150 can have a multilayer structure. In an embodiment, the encapsulation layer 150 can include a first encapsulation layer 152, a second encapsulation layer 154, and a third encapsulation layer 156 that are sequentially stacked, but is not limited thereto. The first encapsulation layer 152, the second encapsulation layer 154, and the third encapsulation layer 156 can include an insulating material. The second encapsulation layer 154 can include a material different from that of the first encapsulation layer 152 and the third encapsulation layer 156. For example, the first encapsulation layer 152 and the third encapsulation layer 156 are inorganic encapsulation layers including an inorganic insulating material, and the second encapsulation layer 154 is an organic encapsulation layer including an organic insulating material. Accordingly, the light emitting elements EL of the display apparatus can be more effectively prevented from being damaged by external moisture and impact.

The touch sensor array 160 can include a first touch insulating layer 162 disposed on the encapsulation layer 150, a bridge electrode BE disposed on the first touch insulating layer 162, a second touch insulating layer 164 covering the bridge electrode BE, a black matrix BM disposed on the second touch insulating layer 164, a third touch insulating layer 166 covering the black matrix BM, a sensor electrode SE disposed on the third touch insulating layer 166, and a fourth touch insulating layer 168 covering the sensor electrode SE. The bridge electrode BE, the black matrix BM, and the sensor electrode SE can be disposed in the non-emission area of each subpixel overlapping the bank insulating layer 132. The sensor electrode SE can be electrically connected to the bridge electrode BE through a contact part CNT (see FIG. 9).

The light control array 170 can include light control elements L disposed on the touch sensor array 160 and a protective layer 172 covering the light control elements L. The light control array 170 can be represented by a light cutting film LCF including a plurality of lenses corresponding to the light control element L.

The light control element L can be disposed on the light emitting area EA of the light emitting element EL to control a path of light generated in the light emitting area EA. The light control element L can control a path of light generated in the light emitting area EA of the light emitting element EL to a wide viewing angle in the first direction X and a narrow viewing angle in the second direction Y. The light control element L can overlap an end portion of at least one of the sensor electrode SE and the black matrix BM in the non-emission area.

Referring to FIGS. 15 and 16, the light control element L according to an embodiment can overlap each light emitting area EA and can have the same size.

Referring to FIG. 17, the light control element L′ according to an embodiment can have an integrated lens shape that is further elongated in the first direction X to overlap the 3-2 light emitting area EA32 and the 3-1 light emitting area EA31 disposed adjacent to each other in the first direction X.

Referring to FIGS. 15 and 17, the light control array 170 according to an embodiment can include a first light control element L, which individually overlaps the first and second light emitting areas EA1 and EA2, and a second light control element L′ shared by the 3-2 and 3-1 light emitting areas EA32 and EA31. The second light control element L′ can have a longer side length in the first direction X than the first light control element L.

The protective layer 172 covering the light control elements L can include an organic insulating material. The refractive index of the protective layer 172 can be smaller than that of the light control elements L. Accordingly, light passing through the light control elements L may not be reflected toward the substrate 110 due to a difference in refractive index from the protective layer 172.

The present disclosure can have the following advantages.

According to an embodiment of the present disclosure, the display apparatus can arrange a plurality of light emitting areas of the same color aligned along any one direction so that the plurality of light emitting areas alternately have a maximum interval and a minimum interval, and can form light emitting areas having a minimum interval through an integrated opening of a mask.

According to an embodiment of the present disclosure, the display apparatus can reduce the minimum interval between the light emitting areas than the minimum gap margin (dead zone) between the openings of the mask, thereby overcoming the dead zone limit of the mask, improving the aperture ratio of the light emitting area, and improving the luminance.

According to an embodiment of the present disclosure, the display apparatus can improve display performance by improving the aperture ratio and luminance of the light emitting area.

According to an embodiment of the present disclosure, since the display apparatus can reduce the current density of the light emitting area by improving the aperture ratio of the light emitting area, deterioration of the light emitting area can be reduced, lifespan can be increased, and low power consumption effects can be achieved.

A display apparatus according to some aspects of the present disclosure can include a display area including a plurality of first pixels and a plurality of second pixels alternately arranged in a first direction, wherein each of the first pixel and the second pixel can include a plurality of light emitting element having different colors, the first pixel and the second pixel can have different light emitting area arrangements of at least one of the plurality of light emitting elements, any one light emitting area of the first pixel and any one light emitting area of the second pixel adjacent to the first direction can be spaced apart by a maximum interval, and any one light emitting area of the second pixel and any one light emitting area of another first pixel adjacent in the first direction can be spaced apart by a minimum interval smaller than the maximum interval.

In the display apparatus according to some aspects of the present disclosure, the light emitting elements adjacent to each other in the first direction with the minimum interval can include an anode electrode independently disposed in each of the light emitting areas adjacent to each other in the first direction, a light emitting layer disposed on the anode electrode and disposed on a bank layer disposed between light emitting areas adjacent to each other in the first direction, and a cathode electrode disposed on the light emitting layer.

In the display apparatus according to some aspects of the present disclosure, each of the first pixel and the second pixel can include a first light emitting element, a second light emitting element, and a third light emitting element arranged in a second direction, which are distinguished from the first direction, wherein a light emitting area of each of the first light emitting element, the second light emitting element, and the third light emitting element can include a long side length in the first direction and a short side length in the second direction.

In the display apparatus according to some aspects of the present disclosure, in each of the first and second pixels, the first light emitting area and the second light emitting area can be aligned with a first center point in the first direction, and the third light emitting area can be aligned with a second center point in the first direction.

In the display apparatus according to some aspects of the present disclosure, the first light emitting area and the second light emitting area of the first pixel can be aligned at a first center point in the first direction, and the third light emitting area of the first pixel can be aligned with a second center point shifted in the 1-1 direction from the first center point in the first pixel.

In the display apparatus according to some aspects of the present disclosure, the first light emitting area and the second light emitting area of the second pixel can be aligned at a third center point in the first direction, and the third light emitting area of the second pixel can be aligned with a fourth center point shifted in a 1-2 direction opposite to the 1-1 direction from the third center point in the second pixel.

The display apparatus according to some aspects of the present disclosure can further include a light control array including a plurality of light control elements overlapped and disposed on the light emitting area of each of the plurality of light emitting elements, wherein each of the plurality of light control elements can include a long side length in the first direction and a short side length in the second direction, wherein each of the plurality of light control elements can control a path of light emitted from the light emitting area to within a cut-off angle in the second direction.

In the display apparatus according to some aspects of the present disclosure, the plurality of light control elements overlapped on the first light emitting area, the second light emitting area, and the third light emitting area of the first pixel can be aligned at the first center point in the first direction, and the plurality of light control elements overlapped on the first light emitting area, the second light emitting area, and the third light emitting area of the second pixel can be aligned with the third center point in the first direction.

In the display apparatus according to some aspects of the present disclosure, the plurality of light control elements can include a first light control element overlapping two third light emitting areas adjacent to each other in the first direction at the minimum interval, wherein the two adjacent third light emitting areas can share the first light control element.

The display apparatus according to some aspects of the present disclosure can further include a light emitting element layer including the plurality of light emitting elements, an encapsulation layer disposed on the light emitting element layer, and a touch sensor array disposed between the encapsulation layer and the light control array.

In the display apparatus according to some aspects of the present disclosure, the touch sensor array can include a bridge electrode, a black matrix, and a sensor electrode overlapped in a non-emission area surrounding the light emitting area of each of the plurality of light emitting elements in the display area and placed with an insulating layer in different layers, wherein the bridge electrode can be electrically connected to the sensor electrode through a contact part disposed in the non-emission area.

In the display apparatus according to some aspects of the present disclosure, the display area can include first to sixth row lines arranged side by side in the second direction, wherein each of the first and fourth row lines can include a plurality of first subpixels in which a plurality of first light emitting areas are arranged along the first direction, each of the second and fifth row lines can include a plurality of second subpixels in which a plurality of second light emitting areas are arranged along the first direction, the third row line can include a plurality of 3-1 subpixels and 3-2 subpixels in which a 3-1 light emitting area and a 3-2 light emitting area are alternately arranged along the first direction, and the sixth row line can include a plurality of 3-2 subpixels and 3-1 subpixels in which the 3-2 light emitting area and the 3-1 light emitting area are alternately arranged along the first direction.

In the display apparatus according to some aspects of the present disclosure, each of the plurality of first light emitting areas can be spaced apart at a first distance in the first direction, each of the plurality of second light emitting areas can be spaced apart at a second distance in the first direction, the 3-1 light emitting area and the 3-2 light emitting area adjacent to each other in the first direction can be spaced apart by the maximum interval, and the 3-2 light emitting area and the 3-1 light emitting area adjacent to each other in the first direction can be spaced apart by the minimum interval.

In accordance with another aspect of the present disclosure, there is provided a display apparatus comprising a pixel array including a pixel circuit and a plurality of subpixels including a light emitting element connected to the pixel circuit; an encapsulation layer disposed on the pixel array to seal a light emitting element layer including a light emitting element; a touch sensor array comprising a black matrix and a sensor electrode disposed on the encapsulation layer and overlapping a non-emission area of the pixel array; and a light control array including a light control element disposed on the touch sensor array and overlapping the light emitting element, wherein in the pixel array, in an N−1th (N is an integer of 2 or more) pixel and an Nth pixel adjacent to each other in the first direction, light emitting elements having a largest light emitting area are spaced apart at a first distance in the first direction, and in the Nth pixel and an N+1th pixel adjacent to each other in the first direction, light emitting elements having a largest light emitting area can be spaced apart at a second distance smaller than the first distance in the first direction.

In the display apparatus according to some aspects of the present disclosure, the light emitting elements adjacent to each other at the second distance in the Nth and N+1th pixels can include an anode electrodes disposed in each light emitting area, independently, a light emitting layer shared by adjacent the light emitting elements, and a cathode electrode shared by the adjacent light emitting elements.

In the display apparatus according to some aspects of the present disclosure, each of the N−1th and Nth pixels can include a first light emitting element, a second light emitting element, and a third light emitting element arranged in a second direction crossing the first direction, wherein each of the first to third light emitting areas of the first to third light emitting elements can include a long side length in the first direction and a short side length in the second direction, and wherein the long side in the first direction of the third light emitting area can be the longest.

In the display apparatus according to some aspects of the present disclosure, first and second light emitting areas of the N−1th pixel can be aligned at a first center point in the first direction within the N−1th pixel, a third light emitting area of the N−1th pixel can be aligned with a second center point shifted in a 1-1 direction from the first center point in the N−1th pixel, and an arrangement structure of the light emitting area of the N+1th pixel can be the same as the light emitting area arrangement of the N−1th pixel.

In the display apparatus according to some aspects of the present disclosure, the light control element can include a long side length in the first direction and a short side length in the second direction, wherein a plurality of light control elements overlapped on the first to third light emitting areas of the N−1th pixel can be aligned with the first center point in the first direction.

In the display apparatus according to some aspects of the present disclosure, the first and second light emitting areas of the Nth pixel can be aligned at the third center point in the first direction within the Nth pixel, and the third light emitting area of the Nth pixel can be aligned with a fourth center point shifted in a 1-2 direction opposite to the 1-1 direction from the first center point in the Nth pixel.

In the display apparatus according to some aspects of the present disclosure, the light control element can include a long side length in the first direction and a short side length in the second direction, wherein a plurality of light control elements overlapped on the first to third light emitting areas of the Nth pixel can be aligned with the third center point in the first direction.

A display apparatus according to some aspects of the present disclosure can include a display area including a plurality of first light emitting areas having a first color and arranged in a first direction, wherein an interval between first light emitting areas adjacent in the first direction can alternate between a maximum interval and a minimum interval smaller than the maximum interval along the first direction.

In the display apparatus according to some aspects of the present disclosure, a bank layer can be disposed between the first light emitting areas adjacent in the first direction, light emitting layers disposed in the first light emitting areas adjacent at the minimum interval can be connected to each other, and light emitting layers disposed in the first light emitting areas adjacent at the maximum interval can be disconnected from each other.

In the display apparatus according to some aspects of the present disclosure, the display area can further include a plurality of second light emitting areas having a second color and arranged in the first direction, and the first and second light emitting areas can be arranged alternately in a second direction crossing the first direction.

In the display apparatus according to some aspects of the present disclosure, an interval between second light emitting areas adjacent in the first direction can be greater than the minimum interval.

In the display apparatus according to some aspects of the present disclosure, the interval between the first light emitting areas adjacent in the first direction can alternate between the maximum interval and the minimum interval along the second direction.

In the display apparatus according to some aspects of the present disclosure, each of the first and second light emitting areas can include a long side length in the first direction and a short side length in the second direction.

In the display apparatus according to some aspects of the present disclosure, the long side length of each of the first emitting areas can be greater than the long side length of each of the second emitting areas.

In the display apparatus according to some aspects of the present disclosure, the second light emitting areas arranged in the second direction can have center points aligned with each other in the second direction, and each of the first light emitting areas arranged in the second direction can have a center point shifted from the center points of the second light emitting areas in the first direction or in a direction opposite to the first direction.

The display apparatus according to some aspects of the present disclosure can further include a light control array including a plurality of light control elements overlapped and disposed on the plurality of first light emitting areas and the plurality of second light emitting areas. The each of the plurality of light control elements can include a long side length in the first direction and a short side length in the second direction, and the each of the plurality of light control elements can control a path of light emitted from each of the plurality of first light emitting areas and the plurality of second light emitting areas to within a cut-off angle in the second direction.

In the display apparatus according to some aspects of the present disclosure, the plurality of light control elements can have center points aligned with the center points of the second light emitting areas in the second direction.

In the display apparatus according to some aspects of the present disclosure, the light control array can include a light control element shared by the first light emitting areas adjacent at the minimum interval.

The display apparatus according to some aspects of the present disclosure can further include a light emitting element layer including a plurality of light emitting elements, an encapsulation layer disposed on the light emitting element layer, and a touch sensor array disposed between the encapsulation layer and the light control array.

In the display apparatus according to some aspects of the present disclosure, the touch sensor array can include a bridge electrode, a black matrix, and a sensor electrode overlapped in a non-emission area of the display area, and the bridge electrode can be electrically connected to the sensor electrode through a contact part disposed in the non-emission area.

A display apparatus according to some aspects of the present disclosure can include a display area including first to sixth row lines extending in a first direction and arranged in a second direction crossing the first direction. Each of the first and fourth row lines includes a plurality of first subpixels in which a plurality of first light emitting areas are arranged along the first direction. Each of the second and fifth row lines includes a plurality of second subpixels in which a plurality of second light emitting areas are arranged along the first direction. The third row line includes a plurality of 3-1 subpixels and 3-2 subpixels in which a 3-1 light emitting area and a 3-2 light emitting area are alternately arranged along the first direction. The sixth row line includes a plurality of 3-2 subpixels and 3-1 subpixels in which the 3-2 light emitting area and the 3-1 light emitting area are alternately arranged along the first direction. In each of the third and sixth row lines, the 3-1 light emitting area and the 3-2 light emitting area adjacent to each other in the first direction can be spaced apart by a maximum interval, and the 3-2 light emitting area and the 3-1 light emitting area adjacent to each other in the first direction are spaced apart by a minimum interval smaller than the maximum interval.

In the display apparatus according to some aspects of the present disclosure, in each of the first and fourth row lines, the plurality of first light emitting areas are spaced apart at a first distance in the first direction, in each of the second and fifth row lines, the plurality of second light emitting areas are spaced apart at a second distance in the first direction, and the minimum interval is smaller than the first distance and the second distance.

A display apparatus according to some aspects of the present disclosure can include a pixel array including a plurality of pixels arranged in a first direction and a second direction crossing the first direction, each of the pixels including a plurality of light emitting elements, one light emitting element among the plurality of light emitting elements having a largest light emitting area greater than that of the remaining light emitting element, an encapsulation layer disposed on the pixel array to seal a light emitting element layer including the light emitting element, a touch sensor array comprising a black matrix and a sensor electrode disposed on the encapsulation layer and overlapping a non-emission area of the pixel array, and a light control array including a light control element disposed on the touch sensor array and overlapping the light emitting element. In in the pixel array, in an N−1th (N is an integer of 2 or more) pixel and an Nth pixel adjacent to each other in the first direction, light emitting elements having the largest light emitting area are adjacent to each other and spaced apart at a first distance in the first direction, and in the Nth pixel and an N+1th pixel adjacent to each other in the first direction, light emitting elements having the largest light emitting area are adjacent to each other and spaced apart at a second distance smaller than the first distance in the first direction.

In the display apparatus according to some aspects of the present disclosure, the light emitting elements adjacent to each other at the second distance in the Nth and N+1th pixels includes an anode electrode disposed in each light emitting element, independently, a light emitting layer shared by adjacent the light emitting elements, and a cathode electrode shared by the adjacent light emitting elements.

In the display apparatus according to some aspects of the present disclosure, each of the N−1th, Nth and N+1th pixels include a first light emitting element, a second light emitting element, and a third light emitting element arranged in the second direction, wherein each of light emitting areas of the first to third light emitting elements can include a long side length in the first direction and a short side length in the second direction, wherein the third light emitting area can have the largest light emitting area.

In the display apparatus according to some aspects of the present disclosure, in each of the N−1th and N+1th pixels, the emitting areas of the first and second light emitting elements can have first center points aligned in the second direction, in each of the N−1th and N+1th pixels, and the largest light emitting area of the third light emitting element has a second center point shifted in the first direction from the first center points. The light control element includes a long side length in the first direction and a short side length in the second direction. In each of the N−1th and N+1th pixels, a center point of the long side length of the light control element overlapped on each of the first to third light emitting elements can be aligned with the first center points in the second direction.

In the display apparatus according to some aspects of the present disclosure, in the Nth pixel, the light emitting areas of the first and second light emitting elements can have third center points aligned in the second direction. In the Nth pixel, the largest light emitting area of the third light emitting element can have a fourth center point shifted in a direction opposite to the first direction from the third center points. The light control element can include a long side length in the first direction and a short side length in the second direction. In the Nth pixel, a center point of the long side length of light control element overlapped on each of the first to third light emitting elements can be aligned with the third center points in the second direction.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display apparatus comprising:
a display area including a plurality of first light emitting areas having a first color and arranged in a first direction,
wherein an interval between first light emitting areas adjacent in the first direction, among the plurality of first light emitting areas, alternates between a maximum interval and a minimum interval along the first direction, and
wherein the minimum interval is smaller than the maximum interval.

2. The display apparatus according to claim 1,
wherein a bank layer is disposed between the first light emitting areas adjacent in the first direction,
wherein light emitting layers disposed in the first light emitting areas adjacent at the minimum interval are connected to each other, and
wherein light emitting layers disposed in the first light emitting areas adjacent at the maximum interval are disconnected from each other.

3. The display apparatus according to claim 1,
wherein the display area further includes a plurality of second light emitting areas having a second color and arranged in the first direction, and
wherein the first and second light emitting areas are arranged alternately in a second direction crossing the first direction.

4. The display apparatus according to claim 3,
wherein an interval between second light emitting areas adjacent in the first direction, among the plurality of second light emitting areas, is greater than the minimum interval.

5. The display apparatus according to claim 3,
wherein the interval between the first light emitting areas adjacent in the first direction alternates between the maximum interval and the minimum interval along the first direction.

6. The display apparatus according to claim 3,
wherein each of the first and second light emitting areas includes a long side length in the first direction and a short side length in the second direction.

7. The display apparatus according to claim 6,
wherein the long side length of each of the first emitting areas is greater than the long side length of each of the second emitting areas.

8. The display apparatus according to claim 3,
wherein the second light emitting areas arranged in the second direction have center points aligned with each other in the second direction, and
wherein each of the first light emitting areas arranged in the second direction has a center point shifted from the center points of the second light emitting areas in the first direction or in a direction opposite to the first direction.

9. The display apparatus according to claim 8, further comprising:
a light control array including a plurality of light control elements overlapped and disposed on the plurality of first light emitting areas and the plurality of second light emitting areas,
wherein each of the plurality of light control elements includes a long side length in the first direction and a short side length in the second direction, and
wherein each of the plurality of light control elements is configured to control a path of light emitted from each of the plurality of first light emitting areas and the plurality of second light emitting areas to within a cut-off angle in the second direction.

10. The display apparatus according to claim 9,
wherein the plurality of light control elements have center points aligned with the center points of the second light emitting areas in the second direction.

11. The display apparatus according to claim 9,
wherein the light control array includes light control elements shared by the first light emitting areas adjacent at the minimum interval.

12. The display apparatus according to claim 9, further comprising:
a light emitting element layer including a plurality of light emitting elements;
an encapsulation layer disposed on the light emitting element layer; and
a touch sensor array disposed between the encapsulation layer and the light control array.

13. The display apparatus according to claim 12,
wherein the touch sensor array includes a bridge electrode, a black matrix, and a sensor electrode overlapped in a non-emission area of the display area, and
wherein the bridge electrode is electrically connected to the sensor electrode through a contact part disposed in the non-emission area.

14. A display apparatus comprising:
a display area including first to sixth row lines extending in a first direction and arranged in a second direction crossing the first direction,
wherein each of the first and fourth row lines includes a plurality of first subpixels in which a plurality of first light emitting areas are arranged along the first direction,
wherein each of the second and fifth row lines includes a plurality of second subpixels in which a plurality of second light emitting areas are arranged along the first direction,
wherein the third row line includes a plurality of 3-1 subpixels and 3-2 subpixels in which a 3-1 light emitting area and a 3-2 light emitting area are alternately arranged along the first direction,
wherein the sixth row line includes a plurality of 3-2 subpixels and 3-1 subpixels in which the 3-2 light emitting area and the 3-1 light emitting area are alternately arranged along the first direction, and
wherein in each of the third and sixth row lines, the 3-1 light emitting area and the 3-2 light emitting area adjacent to each other in the first direction are spaced apart by a maximum interval, and the 3-2 light emitting area and the 3-1 light emitting area adjacent to each other in the first direction are spaced apart by a minimum interval being smaller than the maximum interval.

15. The display apparatus according to claim 14,
wherein, in each of the first and fourth row lines, the plurality of first light emitting areas are spaced apart at a first distance in the first direction,
wherein in each of the second and fifth row lines, the plurality of second light emitting areas are spaced apart at a second distance in the first direction, and
wherein the minimum interval is smaller than each of the first distance and the second distance.

16. A display apparatus comprising:
a pixel array including a plurality of pixels arranged in a first direction and a second direction crossing the first direction, each of the plurality of pixels including a plurality of light emitting elements, one light emitting element among the plurality of light emitting elements having a largest light emitting area being greater than that of one or more remaining light emitting elements;
an encapsulation layer disposed on the pixel array to seal a light emitting element layer including the one light emitting element;
a touch sensor array comprising a black matrix and a sensor electrode disposed on the encapsulation layer and overlapping a non-emission area of the pixel array; and
a light control array including a light control element disposed on the touch sensor array and overlapping the one light emitting element,
wherein in the pixel array,
in an N−1th pixel and an Nth pixel adjacent to each other in the first direction, light emitting elements having the largest light emitting area are adjacent to each other and spaced apart at a first distance in the first direction, where N is an integer of 2 or more, and
in the Nth pixel and an N+1th pixel adjacent to each other in the first direction, light emitting elements having the largest light emitting area are adjacent to each other and spaced apart at a second distance in the first direction, where the second distance is smaller than the first distance.

17. The display apparatus according to claim 16,
wherein the light emitting elements adjacent to each other at the second distance in the Nth and N+1th pixels include:
an anode electrode disposed in each light emitting element independently;
a light emitting layer shared by the adjacent light emitting elements; and
a cathode electrode shared by the adjacent light emitting elements.

18. The display apparatus according to claim 16,
wherein each of the N−1th, Nth and N+1th pixels includes:
a first light emitting element, a second light emitting element, and a third light emitting element arranged in the second direction,
wherein each of light emitting areas of the first to third light emitting elements includes a long side length in the first direction and a short side length in the second direction, and
wherein the third light emitting area has the largest light emitting area.

19. The display apparatus according to claim 18,
wherein in each of the N−1th and N+1th pixels, the light emitting areas of the first and second light emitting elements have first center points aligned in the second direction,
wherein in each of the N−1th and N+1th pixels, the light emitting area of the third light emitting element has a second center point shifted in the first direction from the first center points,
wherein the light control element includes a long side length in the first direction and a short side length in the second direction, and
wherein in each of the N−1th and N+1th pixels, a center point of the long side length of each light control element respectively overlapping one of the first to third light emitting elements is aligned with the first center points in the second direction.

20. The display apparatus according to claim 18,
wherein in the Nth pixel, the light emitting areas of the first and second light emitting elements have third center points aligned in the second direction,
wherein in the Nth pixel, the light emitting area of the third light emitting element has a fourth center point shifted in a direction opposite to the first direction from the third center points, the light control element includes a long side length in the first direction and a short side length in the second direction, and
wherein in the Nth pixel, a center point of the long side length of light control element respectively overlapping one of the first to third light emitting elements is aligned with the third center points in the second direction.
